(19) United States
(12) Patent Application Publication
(10) Pub. No.: US 2012/0114004 A1
(43) Pub. Date: May 10, 2012

(54) NITRIDE SEMICONDUCTOR LASER DEVICE AND METHOD OF MANUFACTURING THE SAME

(75) Inventors: Tomoya SATOH, Osaka (JP); Tomohiro YAMAZAKI, Okayama (JP); Yoshiaki HASEGAWA, Okayama (JP)

(73) Assignee: PANASONIC CORPORATION, Osaka (JP)

(21) Appl. No.: 13/282,798

(22) Filed: Oct. 27, 2011

(30) Foreign Application Priority Data
Nov. 4, 2010 (JP) 2010-247847

(51) Int. Cl. H01S 5/026; H01L 21/302

(52) U.S. Cl. 372/50.1; 438/39; 257/E21.214

(57) ABSTRACT

A nitride semiconductor laser device includes a first semiconductor layer, an active layer, a second semiconductor layer having a ridge portion and a planar portion, a first electrode formed above the ridge portion, and a dielectric film formed on the side wall portion of the ridge portion. A region from a front end face to a predetermined position P is a region A. A region from the predetermined position P to the rear end face is a region B. A thickness of the part of the ridge portion exposed from the dielectric film in the region A is greater than a thickness of the part of the ridge portion exposed from the dielectric film in the region B, and the first electrode is in contact with the ridge portion at least in the region A.

### CROSS REFERENCE TO RELATED APPLICATION

The present application is based on and claims priority of Japanese Patent Application No. 2010-247847 filed on Nov. 4, 2010. The entire disclosure of the above-identified application, including the specification, drawings and claims is incorporated herein by reference in its entirety.

### BACKGROUND OF THE INVENTION

(1) Field of the Invention

The present invention relates to semiconductor laser devices and relates particularly to a semiconductor laser device capable of improving reliability characteristics during high output operations and an amount of change in light output of a far field pattern in a horizontal direction.

(2) Description of the Related Art

In recent years, there has been significant progress in the popularization of digital versatile disc (DVD) equipment which is compatible with Blu-ray Disc (registered trademark) capable of recording high definition (HD) images of digital terrestrial broadcast on a DVD for long hours. Moreover, a three-dimensional display and the like lead to progress in a further increase in storage capacity of an optical disc for the BD-compatible DVD equipment.

In view of such a background, a nitride semiconductor laser with a 405-nm wavelength band which is a light source of the BD-compatible DVD equipment is required to have far field pattern (hereafter called “FFP”) characteristics of high output and stable radiation angles of emitting beams, and there is a strong demand from the market for an output of a pulsed light to be 400 mW or more, and for the FFP characteristics to be about 8 degrees in a horizontal direction and about 18 degrees in a vertical direction.

Higher output of a nitride semiconductor laser device allows an increase in recording speed of an optical disc and enables a multilayer recording. However, in the case where input power to a nitride semiconductor laser is increased for higher output, a temperature on a light-emitting end face of the nitride semiconductor laser increases and causes a catastrophic optical damage (hereafter called COD) and an increase in operating current with constant output, thus leading to a deterioration of the reliability characteristics.

A mechanism for causing COD includes repeating a cycle of heat generation on the light-emitting end face (front end face), a decrease in a band gap of an active layer in the vicinity of the front end face, an increase in light absorption, and heat generation on the front end face.

In order to improve a COD level, there is a method of constituting an end face window structure by injecting ions into or diffusing highly concentrated impurities around the front end face in an infrared laser of a GaAs-based material, whose crystalline structure is a zincblende structure, and a red laser of AlGaInP-based material. This end face window structure enables a well layer of a quantum well active layer and a crystal of a barrier layer to be disordering, to extend a band gap in the quantum well active layer, and to reduce light absorption in the front end face.

However, in a nitride semiconductor laser of a GaN-based material whose crystalline structure is a wurtzite structure, it is difficult to form an end face window structure by the ion injection and the impurity diffusion.

In contrast, Patent Reference 1 (Japanese Unexamined Patent Application Publication No. 2009-212336) discloses a method of forming an end face window structure in a nitride semiconductor laser which is difficult to perform a crystal disordering with use of the ion injection and the impurity diffusion.

In the method disclosed in Patent Reference 1, a pulsed laser with a wavelength of 355 nm, which causes light absorption only in a multiple quantum well active layer made of InGaN/GaN with a narrow band gap and a GaN guide layer, is emitted to the vicinity of a front end face, followed by a heating process. In this way, the multiple quantum well active layer can be disordered by a local generation of high temperature, enabling an end face window structure to be formed.

Moreover, Patent Reference 2 (Japanese Unexamined Patent Application Publication No. 2009-059933) discloses a method of improving the reliability characteristics of a nitride semiconductor laser without depending on the end face window structure.

A technique disclosed in Patent Reference 2 includes a cladding layer having a ridge, a pair of first current blocking layers formed on the cladding layer in both sides of the ridge, and a pair of second current blocking layers which has a larger refractive index than a refractive index of the first current blocking layers with a light-emitting peak wavelength of an active layer, and is in contact with the first current blocking layers on the cladding layer, and is located opposite to each other in both sides of a front end region of the ridge. This enables a decrease in a density of light intensity in the front end face by decreasing light confined around the front end face by the second current blocking layers, thus reducing the deterioration of the front end face.

### SUMMARY OF THE INVENTION

However, the method disclosed in Patent Reference 1 leads to not only the disordering of a crystal of a multiple quantum active layer but also the disordering of a GaN guide layer that has an effect of confining light. In this way, the disordering of the crystal of the GaN guide layer leads to widening a band gap of the GaN guide layer and decreasing a refractive index. Therefore, the effect of confining light in a vertical direction is significantly weakened, making it difficult to simultaneously satisfy the reliability characteristics and the optical characteristics as a nitride semiconductor laser used for an optical disc.

Moreover, the technique disclosed in Patent Reference 2 cannot sufficiently improve the COD level, and significantly decreases the effect of confining light in the vicinity of the front end face when the COD level is being significantly improved. This is why a light distribution in both horizontal and vertical directions significantly expands and the FFP characteristics also decrease to a value that is impossible to use in a nitride semiconductor laser used for an optical disc. As a result, it is difficult to simultaneously satisfy the reliability characteristics and the optical characteristics as a nitride semiconductor laser used for an optical disc.

The present invention has been devised in view of the above-mentioned problems, and has an object to provide a nitride semiconductor laser device satisfying both the reliability characteristics and the optical characteristics and a manufacturing method thereof.

In order to resolve the problems, a nitride semiconductor laser device according to an aspect of the present invention is a nitride semiconductor laser device which has a front end face that is a light-emitting end face, and a rear end face opposite to the front end face, including a first semiconductor layer of a first conductivity type formed above a substrate, an active layer formed above the first semiconductor layer, a second semiconductor layer of a second conductivity type which is formed above the active layer and includes a ridge portion and a planar portion, an electrode formed above the ridge, and a dielectric film formed on a part of a side wall portion of the ridge portion and extending to the planar portion, wherein a part of the side wall portion of the ridge portion is exposed from the dielectric film along a direction from the front end face to the rear end face, where a region from the front end face to a predetermined position between the front end face and the rear end face is determined as a region A, and a region from the predetermined position to the rear end face is determined as a region B, a thickness of the exposed part of the ridge portion in the region A is greater than a thickness of the exposed part of the ridge portion in the region B, the exposed part being exposed from said dielectric film, and in at least the region A, the electrode is in contact with the part of the ridge portion exposed from the dielectric film.

This leads to an improvement of properties of heat dissipation to the first electrode of heat generated by a Joule loss and an internal loss in the second semiconductor layer in the region A. This leads to a decrease in heat generation in the front end face and an increase in the COD level. Furthermore, the FFP characteristics can be stabilized because an amount of change by light output of a horizontal FFP can be reduced by reducing heat generation in the vicinity of the front end face.

A nitride semiconductor laser device according to another aspect of the present invention is a nitride semiconductor laser device which has a front end face that is a light-emitting end face, and a rear end face opposite to the front end face, including a first semiconductor layer of a first conductivity type formed above a substrate, an active layer formed above the first semiconductor layer, a second semiconductor layer of a second conductivity type which is formed above the active layer and includes a ridge portion and a planar portion, and an electrode formed above the ridge portion, and a dielectric film formed on a part of a side wall portion of the ridge portion and extending to the planar portion, wherein a part of the side wall portion of the ridge portion is exposed from the dielectric film along a direction from the front end face to the rear end face, where a region from the front end face to a predetermined first position between the front end face and the rear end face is determined as a non-current injection region, a region from the first position to a predetermined second position between the first position and the rear end face is determined as a region A, and a region from the second position to a predetermined third position between the second position and the rear end face is determined as region B, a thickness of the exposed part of the ridge portion in the region A is greater than a thickness of the exposed part of the ridge portion in the region B, the exposed part being exposed from the dielectric film, and in at least the region A, the electrode is in contact with the part of the ridge portion exposed from the dielectric film.

Furthermore, it is preferable that the predetermined third position be a position of the rear end face in the nitride semiconductor laser device according to another aspect of the present invention. Furthermore, it is preferable that a region from the predetermined third position to the rear end face also be a non-current injection region in the nitride semiconductor laser device according to another aspect of the present invention.

Furthermore, it is preferable that a length between the front end face and the predetermined first position be 10 μm or less in the nitride semiconductor laser device according to another aspect of the present invention.

Furthermore, in the nitride semiconductor laser device according to one or another aspect of the present invention, it is preferable that a difference in thickness between the exposed part of the ridge portion in the region A and the exposed part of the ridge portion in the region B be 20 nm or more, the exposed part being exposed from the dielectric film.

Furthermore, in the nitride semiconductor laser device according to one or another aspect of the present invention, it is preferable that a length of the region A in the direction from the front end face to the rear end face be between 10 μm and 200 μm inclusive.

Furthermore, in the nitride semiconductor laser device according to one or another aspect of the present invention, it is preferable that the dielectric film mainly include silicon dioxide (SiO2), zirconium dioxide (ZrO2), silicon nitride (SiN), or tantalum oxide (Ta₂O₅).

Furthermore, in the nitride semiconductor laser device according to one or another aspect of the present invention, it is preferable that the electrode be made of at least one metal selected from a group consisting of palladium (Pd), titanium (Ti), platinum (Pt), gold (Au), nickel (Ni), chromium (Cr), and molybdenum (Mo), or be made of an alloy of the metals.

Furthermore, in the nitride semiconductor laser device according to one or another aspect of the present invention, it is preferable that an absorption layer for absorbing light with an oscillation wavelength of the nitride semiconductor laser be formed above the planar portion in the region A.

Furthermore, in the nitride semiconductor laser device according to one or another aspect of the present invention, it is preferable that the absorption layer be provided at a distance of 1.2 μm to 3.3 μm inclusive from a center of the ridge portion, the distance being in a width direction of the ridge portion, and a thickness of the part of the ridge portion in the region A, is largest in a position where the distance between the absorption layer and the center of the ridge portion is smallest, the exposed part being exposed from the dielectric film.

Furthermore, in the nitride semiconductor laser device according to one or another aspect of the present invention, it is preferable that the second semiconductor layer include a cladding layer and a contact layer formed above the cladding layer, the cladding layer include a ridge and the planar portion on a surface, a width of the contact layer be the same as a width of a top face of the ridge, and the ridge portion of the second semiconductor layer be composed of the ridge of the cladding layer and the contact layer.

Moreover, a method of manufacturing a nitride semiconductor laser device according to an aspect of the present invention is a method of manufacturing the nitride semiconductor laser device which has a front end face that is a light-emitting end face, and a rear end face opposite to the front end face, including (i) sequentially forming, above a substrate, a first cladding layer of a first conductivity type, an active layer, a second cladding layer of a second conductivity type, and a contact layer of the second conductivity type, (ii) forming a ridge portion and a planar portion by selective etching the second cladding layer and the contact layer, (iii) forming, above the planar portion, a first dielectric film to cover the ridge portion, (iv) selectively etching the first dielectric film on the planar portion, and forming, in the etched portion, an absorption layer having a thickness smaller than a thickness of the first dielectric film, (v) forming a second dielectric film on the first dielectric film and on the absorption layer, (vi) selectively exposing a top face and a part of a side of the ridge portion from the first dielectric film and the second dielectric film by etching the first dielectric film and the second dielectric film, and (vii) forming an electrode to cover at least the exposed ridge portion, and where a region from the front end face to a predetermined position between the front end face and the rear end face is determined as a region A, and a region from the predetermined position to the rear end face is determined as a region B, the absorption layer is formed in the region A , a thickness of the exposed part in the region A is greater than a thickness of the exposed part in the region B, and the electrode is in contact with the exposed part of the ridge portion at least in the region A.

With the nitride semiconductor laser device according to an aspect of the present invention, both the reliability characteristics and the optical characteristics can be simultaneously satisfied.

With the nitride semiconductor laser device according to an aspect of the present invention, it is possible to obtain the nitride semiconductor laser device which can simultaneously satisfy both the reliability characteristics and the optical characteristics.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a plan view of the nitride semiconductor laser device according to the first embodiment of the present invention;

FIG. 2 is a cross-sectional view in a region A of the nitride semiconductor laser device according the first embodiment of the present invention;

FIG. 3 is a cross-sectional view in a region B of the nitride semiconductor laser device according the first embodiment of the present invention;

FIG. 4 is a table showing examples of an Al composition, an In composition, and a thickness in each of the layers of the nitride semiconductor laser device according to the first embodiment of the present invention;

FIG. 5 is a graph showing a result of a COD assessment of the nitride semiconductor laser device according to the first embodiment of the present invention;

FIG. 6 illustrates the processes of forming dielectric films in the region A and the region B in a method of manufacturing the nitride semiconductor laser device according the first embodiment of the present invention;

FIG. 7 is a plan view of the nitride semiconductor laser device according to the second embodiment of the present invention; and

FIG. 8 is a cross-sectional view of a region C (non-current injection region) of the nitride semiconductor laser device according to the second embodiment of the present invention.

### DESCRIPTION OF THE PREFERRED EMBODIMENTS

Hereafter, a nitride semiconductor laser device and a manufacturing method thereof according to the embodiments of the present invention shall be described with reference to the drawings. It is noted that measurement and the like of components exemplified in the embodiment are appropriately changed depending on a structure of a device to which the present invention is applied and a variety of conditions and that the present invention is not limited to such exemplifications. Moreover, measurement and the like do not strictly coincide with those in each of the figures.

### First Embodiment

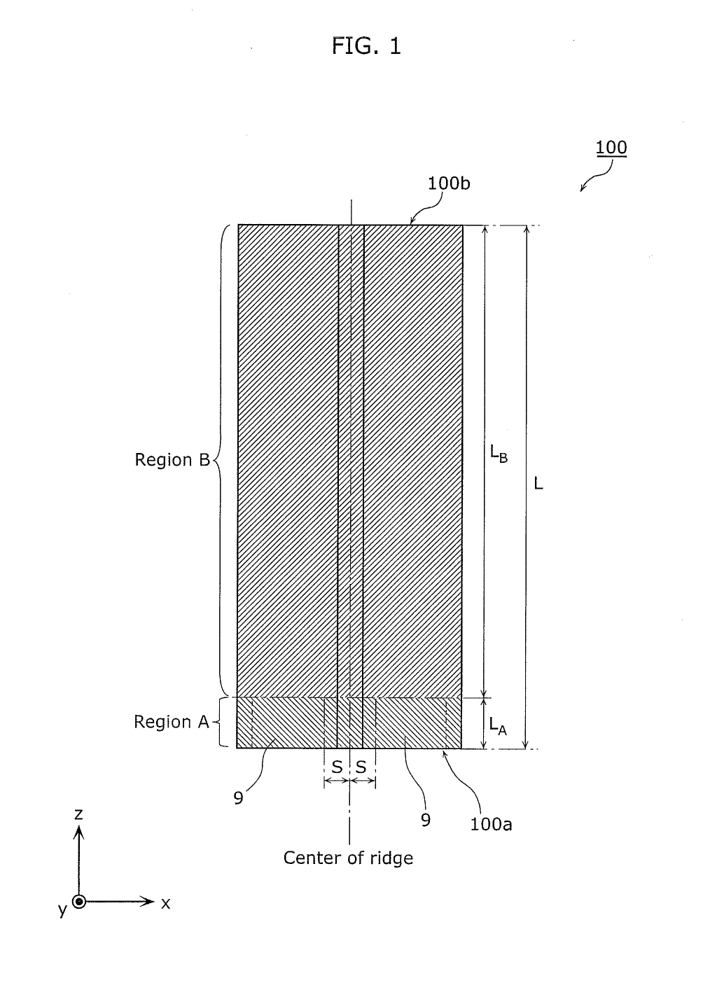

First, a structure of the nitride semiconductor laser device according to the first embodiment of the present invention shall be described with use of FIGS. 1 to 4.

FIG. 1 is a plan view of a nitride semiconductor laser device 100 according to the first embodiment of the present invention. In FIG. 1, a z axis direction is a resonance direction of the nitride semiconductor device 100.

As shown in FIG. 1, the nitride semiconductor laser device 100 according to the first embodiment of the present invention includes a front end face 100a that is a light-emitting end face that emits a laser beam, and a rear end face 100b that is located opposed to the front end face 100a in the z axis direction. A region from the front end face 100a to the rear end face 100b is divided into a region A and a region B. The region A in the vicinity of the front end face 100a is a region from the front end face 100a to a predetermined position P between the front end face 100a and the rear end face 100b. The region B is a region from the predetermined position P to the rear end face 100b. Therefore, the predetermined position P is included in a borderline between the region A and the region B.

In the nitride semiconductor laser device 100 according to the present embodiment, in the case where an overall length of a laser resonator is determined as L and lengths of the region A and the region B in a direction of the resonator (z axis direction) are determined as L_{A} and L_{B}, respectively, L (L_{A}+L_{B}) is 800 μm, L_{A} is 40 μm, and L_{B} is 760 μm.

Moreover, in the region A, a light absorption layer 9 is formed at a predetermined interval S from the center of the ridge portion so as to prevent an FFP waveform turbulence in a horizontal direction (x axis direction). The light absorption layer 9 is made of a semiconductor material such as amorphous silicon (hereafter called amorphous Si) or silicon (hereafter called Si) so as to absorb light of a 405-nm band that is an oscillation wavelength of the nitride semiconductor laser device 100. When the light absorption layer 9 is formed at a position such that the interval S is appropriate, the light absorption layer 9 absorbs a ripple component which is generated by interference between light distributed in the horizontal direction and light, for example, reflected from the front end face 100a. This enables the light absorption layer 9 to remove the ripple component of the light distribution in the horizontal direction, thus improving the

FFP waveform turbulence in the horizontal direction. It is noted that it is preferable that the light absorption layer 9 be provided in a position such that a distance between the light absorption layer 9 and the center of the ridge portion (interval S) is from 1.2 μm to 3.3 μm inclusive in a width direction (x axis direction) of the ridge portion, and the interval S in the present embodiment is set to be 1.5 μm.

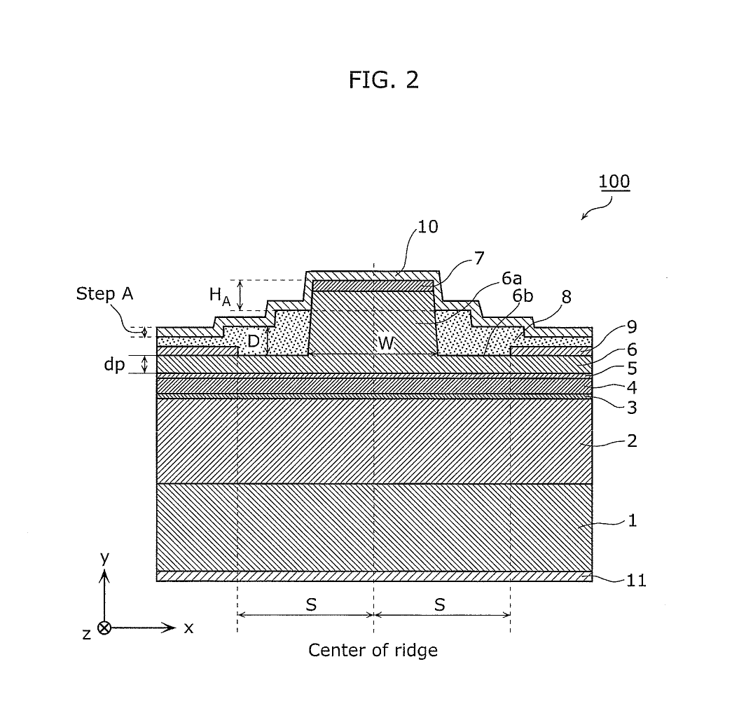

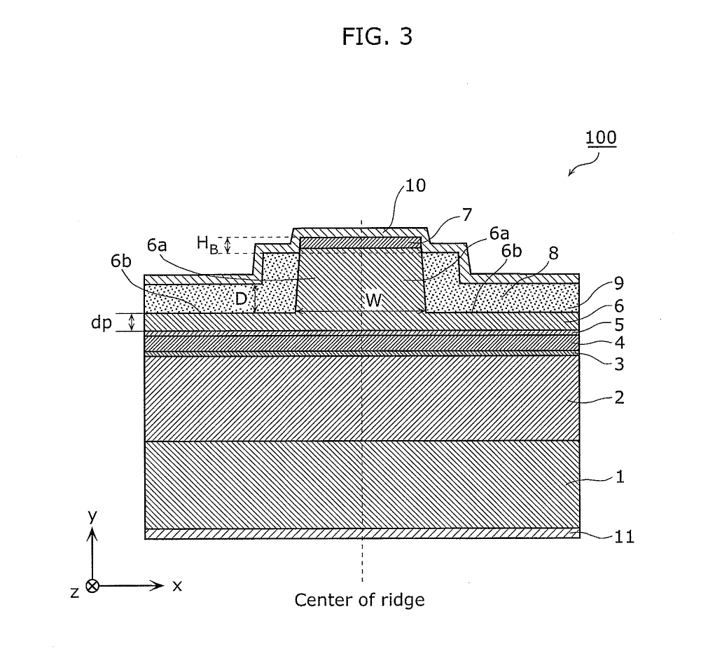

Next, a cross-sectional structure of the nitride semiconductor laser device 100 according to the first embodiment of the present invention shall be described with use of FIG. 2 and FIG. 3. First, the cross-sectional structure in the region A of the nitride semiconductor laser device 100 as shown in FIG. 1 shall be described with use of FIG. 2. FIG. 2 is a cross-sectional view in the region A of the nitride semiconductor laser device according to the first embodiment of the present invention.

As shown in FIG. 2, the nitride semiconductor laser device 100 according to the first embodiment of the present invention is a GaN semiconductor laser diode made of a III-V group nitride semiconductor material in an InAIGaN series, and includes a substrate 1, a first cladding layer 2 of a first conductivity type, a light guide layer 3 of the first conductivity type, an active layer 4, an electron blocking layer 5 of a second conductivity type different from the first conductivity type, a second cladding layer 6 of the second conductivity type, a contact layer 7 of the second conductivity type, and a dielectric film 8. Furthermore, the light absorption layer 9, a first electrode 10, and a second electrode 11 are also included. Hereafter, each of the components of the nitride semiconductor laser device 100 shall be described in detail. It is noted that in each of the components, x is determined as Al composition and y is determined as In composition.

The substrate 1 is a semiconductor substrate having a face and another face opposing the face, and an n-type GaN substrate can be used, for example, for the substrate 1.

The first cladding layer 2 is a semiconductor layer of the first conductivity type, and is formed on one face (surface) of the substrate 1. In the present embodiment, the first cladding layer 2 is made of n-type AlₓGa₁₋ₓN.

The light guide layer 3 is a semiconductor layer of the first conductivity type and is formed on the first cladding layer 2. In the present embodiment, the light guide layer 3 is made of n-type AlₓGa₁₋ₓN.

The active layer 4 is a quantum well active layer composed of a well layer and a barrier layer, and is formed on the light guide layer 3. In the present embodiment, the active layer 4 is a quantum well active layer composed of a well layer and a barrier layer, both made of In_{y}Ga_{1-y}N.

The electron blocking layer 5 is a semiconductor layer of the second conductivity type, and is formed on the active layer 4. The electron blocking layer 5 is formed to reduce an electron overflow from the active layer 4, and is made of p-type AlₓGa₁₋ₓN in the present embodiment. The second cladding layer 6 is a semiconductor layer of the second conductivity type, and is formed on the electron blocking layer 5. In the present embodiment, the first cladding layer 2 is made of p-type AlₓGa₁₋ₓN.

Moreover, the second cladding layer 6 includes a ridge 6a and a planar portion 6b on the surface. The ridge 6a has a convex cross section, and as shown in FIG. 1, is formed in a stripe-like shape that extends along a z axis direction. The planar portion 6b is a region where the ridge 6a is not formed on the second cladding layer 6, and is a flat region that is formed on both sides of the ridge 6a. Therefore, on the second cladding layer 6, the planar portion 6b is configured to have a thickness smaller than a thickness of the ridge 6a (height of the ridge).

The contact layer 7 is a semiconductor layer of the second conductivity type, and is formed on the ridge 6a of the second cladding layer 6. In the present embodiment, the contact layer 7 is made of p-type GaN. It is noted that a width of the contact layer 7 is equal to a width of the top face of the ridge 6a.

In the present embodiment, the ridge portion is composed of the ridge 6a of the second cladding layer 6 and the contact layer 7. The ridge position is formed in a stripe-like shape by a dry etching technique such as a reactive ion etching technique, after layering of the second cladding layer 6 and the contact layer 7. Moreover, the ridge portion is made into a mesa shape such that current is injected into the active layer 4 and light is confined. It is noted that in the present embodiment, the dry etching is performed such that a condition for a single transverse mode oscillation meets around an oscillation threshold current, a ridge width W in a base of the ridge 6a is 1.4 μm, and a thickness dp of the planar portion 6b on the second cladding layer 6 is 50 nm.

The dielectric film 8 is a layer for constricting current and confining light, and extends along from a side wall portion of the ridge portion to the planar portion 6b. More specifically, the dielectric film 8 is successively formed from a part of a side of the ridge 6a on the second cladding layer 6 to the planar portion 6b.

In the present embodiment, the dielectric film 8 is formed on a lower side (on the base side) of sides of the ridge 6a, but is not formed on an upper side of sides of the ridge 6a or sides of the contact layer 7. Therefore, the dielectric film 8 is constituted such that a part of a side wall portion of the ridge portion is exposed from the dielectric film 8, in other words, such that a part of the upper side on the sides of the ridge 6a and the contact layer 7 are exposed from the dielectric film 8, and the upper part of the sides of the ridge 6a and the contact layer 7 are not in contact with the dielectric film 8. Moreover, an exposed part of the side wall portion of the ridge portion is exposed from the dielectric film 8 along a direction (z axis direction) from the front end face 100a to the rear end face 100b. Assume that a thickness of the part of the ridge portion is H_{A}, which part is exposed from the dielectric film 8 in the region A (a part where the dielectric film 8 is not formed), in other words, a thickness of where the second cladding layer 6 and the contact layer 7 are exposed from the dielectric film 8 in the side wall portion of the ridge portion in the region A.

Here, the dielectric film 8 can be composed of a monolayer film made of one of the dielectric materials such as silicon dioxide (SiO₂), zirconium dioxide (ZrO₂,), silicon nitride (SiN), and tantalum oxide (Ta₂O₅), or a multilayer film stacked with two or more layers of these materials. A pattern of the dielectric film 8 made of these materials can be formed with use of a photolithographic technique. In the present embodiment, the dielectric film 8 is composed of a SiO₂ film.

It is noted that in the present embodiment, a thickness D, shown in FIG. 2, of a portion of the dielectric film 8 in the region A is 150 nm.

The light absorption layer 9, as described above, is formed on a desired position on the planar portion 6b of the second cladding layer 6 so as to absorb light with an oscillation wavelength. The light absorption layer 9 is formed by vapor deposition of a semiconductor material such as amorphous Si or Si.

The first electrode 10 is a p-side electrode and is configured to be in contact with the part of the ridge portion exposed from the dielectric film 8 at least in the region A. In the present embodiment, the first electrode 10 is configured to be in contact with the ridge portion exposed in both the region A and the region B. In other words, the first electrode 10 is formed on a top face or a side of the contact layer 7, a part exposed from the dielectric film 8 in the side wall portion of the ridge 6a of the second cladding layer 6, and on the dielectric film 8. In this way, since the first electrode 10 is thus in contact with the exposed part of the ridge portion, heat generated in the ridge portion can be efficiently dissipated.

In the present embodiment, it is preferable that the first electrode 10 be made of a metal capable of forming a good contact with a p-type GaN layer, and can be made of at least one of the metals selected from a group consisting of palladium (Pd), titanium (Ti), platinum (Pt), gold (Au), nickel (Ni), chromium (Cr), and molybdenum (Mo), or an alloy of these metals.

The second electrode 11 is an n-side electrode, and is formed on another face (reverse face) of the substrate 1. In the present embodiment, the second electrode 11 is formed to have a contact connection with the substrate 1 of an n-type GaN substrate, and is made of a multilayer film composed of a three-layer metal film of Ti, Pt, and Au from a side of the substrate 1.

Next, the cross-sectional structure in the region B of the nitride semiconductor laser device 100 shown in FIG. 1 shall be described with use of FIG. 3. FIG. 3 is a cross-sectional view in the region B of the nitride semiconductor laser device according to the first embodiment of the present invention. It is noted that in FIG. 3, components similar to components in FIG. 2 are provided with the same numerals. Moreover, in FIG. 3, descriptions will focus on components different from FIG. 2, and description about the same components will be omitted.

As illustrated in FIG. 3, the light absorption layer 9 is not formed in the region B, which is different from in the region A.

Moreover, the formation of the dielectric film 8 in the region B is performed concurrently with the formation of the dielectric film 8 in the region A. In the region B, similarly to the region A, the dielectric film 8 is formed on a lower side (on the base side) of sides of the ridge 6a, but is not formed on an upper side of sides of the ridge 6a or sides of the contact layer 7. Therefore, the dielectric film 8 is constituted such that a part of a side wall portion of the ridge portion is exposed from the dielectric film 8 along the z axis direction, and the upper portions of the sides of the ridge 6a and the contact layer 7 are not in contact with the dielectric film 8.

Here, assume that a thickness of the part of the ridge portion is H_{B}, which part is exposed from the dielectric film 8 in the region B (a part where the dielectric film 8 is not formed), in other words, a thickness of where the second cladding layer 6 and the contact layer 7 are exposed from the dielectric film 8 in the side wall portion of the ridge portion in the region B.

In the present embodiment, an exposed part of the ridge portion in the region A is configured to have the thickness H_{A} that is larger than the thickness H_{B} of the exposed part in the region B. In other words, there is a relationship of H_{A}>H_{B}. In the present embodiment, H_{A} is set at 150 nm and H_{B} is set at 100 nm.

It is noted that in the present embodiment, a thickness D, shown in FIG. 3, of a portion of the dielectric film 8 in the region B is 150 nm.

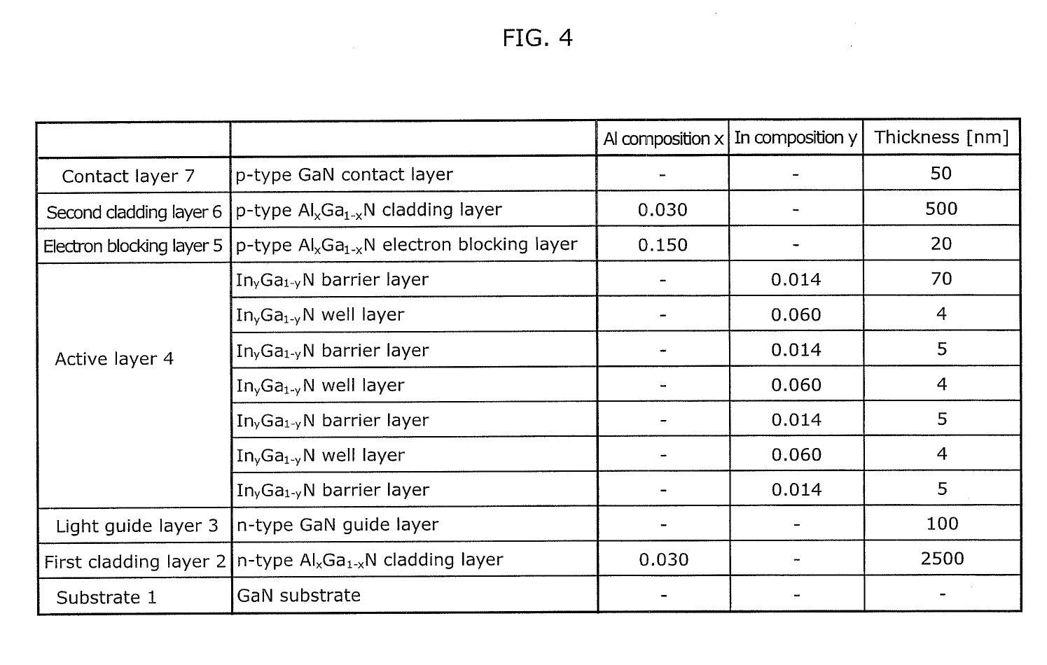

Examples of an Al composition, an In composition, and a thickness of each of the layers of the nitride semiconductor laser device 100 according to the first embodiment of the present invention configured in this way will be shown in FIG. 4. The Al composition, the In composition, and the thickness, all shown in FIG. 4, are such that a light output is 400 mW or more, and the FFP characteristics are set at 8 degrees in a horizontal direction and at 18 degrees in a vertical direction.

Next, an operation of the nitride semiconductor laser device 100 according to the first embodiment of the present invention shall be described hereafter.

A loss in the nitride semiconductor laser, as similarly to a general semiconductor laser, is generally divided into an electrical loss and an optical loss. The electrical loss and the optical loss are a source of heat generation in the nitride semiconductor laser, thus significantly influencing the reliability characteristics of a high output nitride semiconductor laser.

An electrical loss, caused by a Joule loss by a series resistance component in a ridge portion, accounts for most of the electrical loss, and is also caused by a contact resistance in the contact layer 7 mainly made of p-type GaN and a series resistance in the second cladding layer 6 made of p-type AlₓGa₁₋ₓN. These resistance components are dependent on the ridge width W, and can be reduced by widening the ridge width W. However, the nitride semiconductor laser device according to the first embodiment of the present invention shown in FIG. 1 and FIG. 2 which is configured to meet a single transverse mode oscillation condition is required to have the ridge width W at a small value of 1.4 μm or less. Therefore, it cannot be hoped that a series resistance is significantly decreased.

Moreover, an internal loss in a semiconductor laser that is an optical loss is largely affected by absorption of free carriers by impurities injected into the second cladding layer 6 mainly made of p-type AₗxGa₁₋ₓN. As a way to reduce the internal loss in the nitride semiconductor laser device, a method of decreasing a concentration of impurities in the second cladding layer 6 can be considered. However, an excessive decrease in the concentration of impurities leads to a decrease in a conductivity of the second cladding layer 6 and an increase in the series resistance component, thus having adverse effects, such as an increase in operating voltage, on other characteristics.

As described above, there is a trade-off relationship between the Joule loss that is the electrical loss and the internal loss that is the optical loss, and it is difficult to simultaneously decrease both of them. Therefore, such that the reliability characteristics defined by COD and the like, of the nitride semiconductor laser device, are improved, it is extremely important to improve dissipation characteristics of heat generated by the Joule loss and the internal loss.

Therefore, in the nitride semiconductor laser device 100 according to the first embodiment of the present invention, H_{A}>H_{B} is set for a relationship of a thickness of where the second cladding layer 6 made of p-type AlₓGa₁₋ₓ N and the contact layer 7 made of p-type

GaN in the region A and the region B are exposed from the dielectric film 8. This allows an improvement in dissipation of heat to the first electrode 10 (p-side electrode), which heat is generated by the Joule loss and the internal loss in the second cladding layer 6 in the region A. This is possible because heat conductivity of the first electrode 10 that is a metal is higher than heat conductivity of a material constituting the dielectric film 8, and because heat dissipation properties in the vicinity of the front end face 100a can be improved by an increase in an area of contact between a side wall portion of the ridge portion in the region A (the ridge 6a of the second cladding layer 6 and the contact layer 7), which is a product of a length L_{A} of a resonator direction of the region A and a thickness H_{A} of the exposed part, and the first electrode 10 (p-side electrode). This enables the front end face 100a to reduce heat generation and enables the COD level to be higher than a nitride semiconductor device that satisfies H_{A}=H_{B}.

It is noted that in the case where H_{g} is greater than H_{A}, heat conductivity in the region B is improved but an area of contact between the ridge portion and the first electrode 10 increases, thus increasing an internal loss influenced by a light absorption loss. This results in a deterioration of laser characteristics such as a decrease in luminescence efficiency and an increase in threshold current. Therefore, it is preferable that a thickness of exposure of the second cladding layer 6 and the contact layer 7 from the dielectric film 8 be increased only in the region A in the vicinity of the front end face 100a.

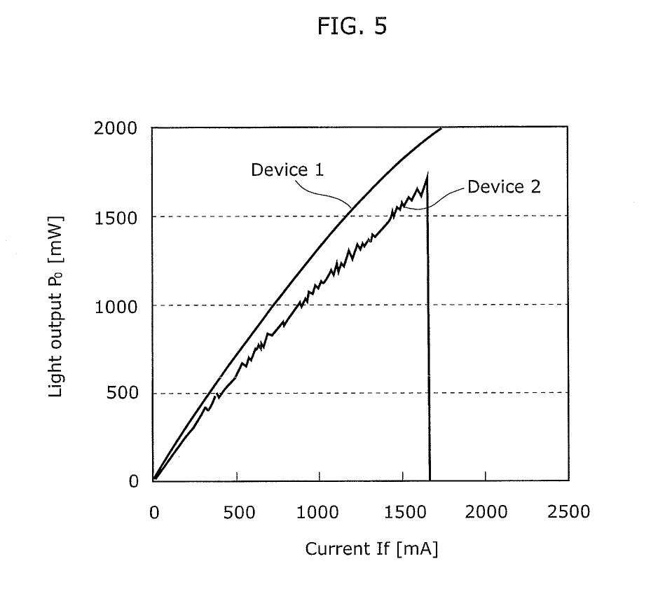

Next, the reliability characteristics and the FFP characteristics of the nitride semiconductor laser device according to the first embodiment of the present invention shall be described with use of FIG. 5.

FIG. 5 is a graph showing a result of a COD assessment of a device packed into a CAN package by junction-up after a trial fabrication of the nitride semiconductor laser device 100 according to the first embodiment of the present invention. In FIG. 5, a device 1 is the nitride semiconductor laser device 100 according to the first embodiment of the present invention and the device which has a step A in the region A and satisfies H_{A}>H_{B}. It is noted that in the device 1, the thickness H_{A} is set at 150 nm the thickness H_{B} is set at 100 nm. Meanwhile, a device 2 is a nitride semiconductor laser device that does not have the step A in the region A but satisfies H_{A}=H_{B}. It is noted that in the device 2, the thickness H_{A} and the thickness H_{B} are both set at 100 nm.

As shown in FIG. 5, COD was not generated in the device 1 according to the first embodiment of the present invention that satisfies H_{A}>H_{B} even though a light output reaches 2,000 mW. In contrast, COD was generated in the device 2 according to a comparison example of H_{A}=H_{B} when a light output reaches around 1,700 mW.

Moreover, after assessing an amount of change in a horizontal FFP from a low output to a high output of each of the device 1 and the device 2, the device 1 had 0.32 degree in the amount of change in the horizontal FFP of a light output from 5 mW to 300 mW at a room temperature. Meanwhile, the device 2 had 0.52 degree in the amount of change in the horizontal FFP, thus representing that the device 1 can decrease, more than the device 2, the amount of change relative to the light output of the horizontal FFP.

Furthermore, based on a relationship between a chip temperature and an oscillation wavelength of each of the device 1 and the device 2, a value of increase in the chip temperature was estimated for each of the device 1 and the device 2 based on a light output ranging from 5 mW to 300 mW. As a result, the value of increase in the temperature of the device 1 from 5 mW to 300 mW in a light output was 35.6 degrees Celsius. In contrast, the value of increase in temperature of the device 2 as estimated in the same way was 38.3 degrees Celsius. This reveals that the device 1, compared with the device 2, can reduce an increase in temperature at the time of the high output. Furthermore, a decrease in an amount of change of a horizontal FFP relative to the light output by decreasing heat generation in the vicinity of the front end face also leads to stabilization of the FFP characteristics of a high output nitride semiconductor laser device used for an optical disc.

In this way, by determining H_{A}>H_{B} for a relationship between the thickness H_{A} of exposure of the ridge portion in the region A from the dielectric film 8 and the thickness H_{B} of exposure of the ridge portion in the region B from the dielectric film 8, heat dissipation properties in the region A on the front end face 100a side can be improved, resulting in an improvement in the COD level and a decrease in the amount of change in the horizontal FFP relative to the light output.

It is noted that it is preferable that the thickness H_{A} in the region A be greater than the thickness H_{B} in the region B by 20 nm or more. In other words, it is preferable that the thickness H_{A} be larger than the thickness H_{B} and a difference between the thickness H_{A} and the thickness H_{B} be 20 nm or more (H_{A}≧H_{B}+20 nm). This is because in the case where the difference between H_{A} and H_{B} is less than 20 nm, an area of contact decreases between the side wall portion of the ridge portion (the ridge 6a of the second cladding layer 6 and the contact layer 7), and the first electrode 10, the effect of heat dissipation decreases, and an improvement in the COD level cannot be expected. Moreover, it is preferable that the length L_{A} of a resonator direction of the region A be from 10 μm to 200 μm inclusive. This is because in the case where L_{A} is less than 10 μm, an area of contact decreases between the side wall portion of the ridge portion that is the product of L_{A} and H_{A} and the first electrode 10, the effect of heat dissipation decreases, and the improvement in the COD level cannot be expected. Moreover, this is because in the case where L_{A} is more than 200 μm, an area of contact significantly increases between the side wall portion of the ridge portion that is the product of L_{A} and H_{A}, and the first electrode 10, and an internal loss from the absorption by the first dielectric film 10 significantly increases, thus having adverse effects, such as an increase in threshold current and a decrease in luminescence efficiency, on the laser characteristics.

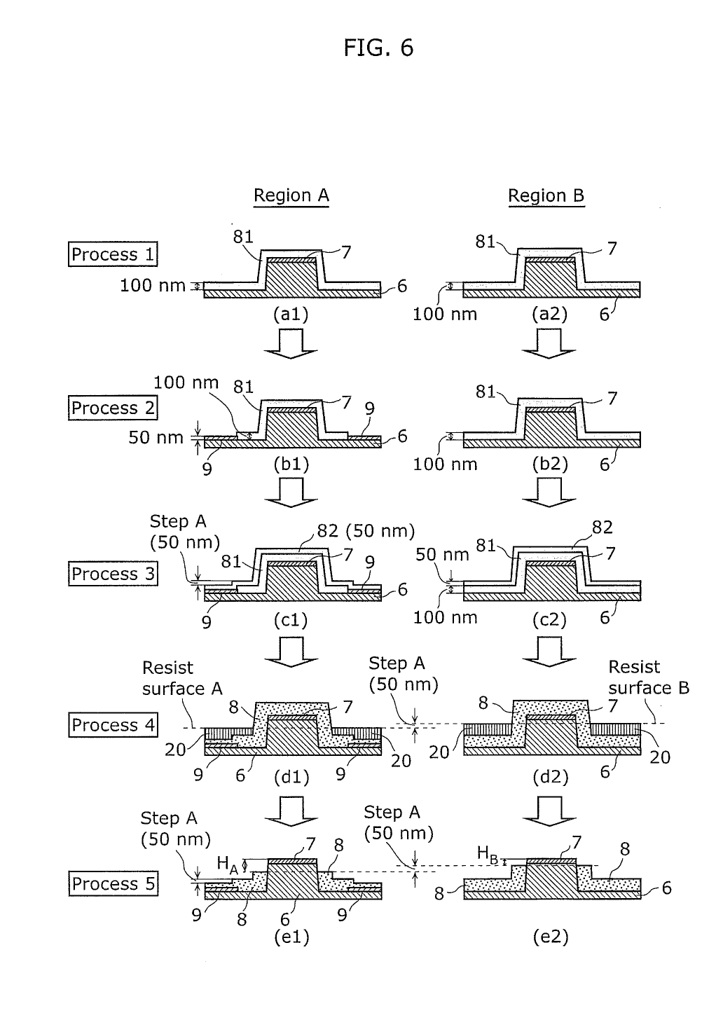

Next, a method of manufacturing the nitride semiconductor laser device 100 according to the first embodiment of the present invention shall be described with use of FIG. 6. FIG. 6 illustrates a process flow according to formation of the dielectric film 8 in the region A and the region B, in the method of manufacturing the nitride semiconductor laser device 100 according to the first embodiment of the present invention.

First, although not illustrated, with use of a metal organic chemical vapor deposition (MOCVD) method, a nitride semiconductor multilayer structure is formed by sequentially depositing, on the substrate 1 made of an n-type GaN substrate, the first cladding layer 2 made of n-type AlₓGa₁₋ₓ N, the light guide layer 3 made of AlₓGa₁₋ₓN, the active layer 4 having a multiple quantum well layer structure composed of an In_{y}Ga_{1-y}N well layer and a barrier layer, the electron blocking layer 5 made of p-type AlₓGa₁₋ₓN, the second cladding layer 6 made of p-type AlₓGA₁₋ₓN, and the contact layer 7 made of p-type GaN (semiconductor multilayer structure formation step).

Next, by forming a mask pattern in a stripe-like shape on the contact layer 7 and performing dry etching such as reactive ion etching, etching is selectively performed on the contact layer 7 and the second cladding layer 6. This enables the ridge portion in a stripe-like shape (the ridge 6a and the contact layer 7) and the planar portion 6b to be formed (ridge portion formation step). In the present embodiment, a mesa-shaped ridge portion is formed for an injection of current into the active layer 4 and light confinement. Moreover, in the present embodiment, dry etching is performed such that the ridge width W of the ridge 6a is 1.4 μm and a thickness of the planar portion 6b is 50 nm.

Next, the dielectric film 8 is formed. A method of forming the dielectric film 8, as shown in FIG. 6, is performed in the order: formation of a first dielectric film 81 (Process 1), formation of the light absorption layer 9 (Process 2), formation of a second dielectric film 82 (Process 3), an exposure of an opening surface (Process 4), and an etching of the dielectric film 8 (Process 5). Hereafter, in accordance with FIG. 6, the method of forming the dielectric film 8 shall be described in detail.

First, as shown in (a1) and (a2) of FIG. 6, in Process 1, with use of the chemical vapor deposition (CVD) method, the first dielectric film 81 made of SiO₂ is formed with a thickness of 100 nm on an exposed part of the contact layer 7 (the top face and the side surface) and an exposed part of the second cladding layer 6 (all sides of the ridge 6a and a whole surface of the planar portion 6b) in the whole of the region A and the region B so as to cover the ridge portion (first dielectric film formation step).

Next, as shown in (b1) and (b2) of FIG. 6, in Process 2, after removing the first dielectric film 81 by patterning and etching in a range forming the light absorption layer 9 in the region A, the light absorption layer 9 having a smaller thickness than a thickness of the first dielectric film 81 is formed on a part of which the first dielectric film 81 has been removed with use of lift-off and other methods (absorption layer formation step). In the present embodiment, the light absorption layer 9 is formed with a thickness of 50 nm.

At this time, a part where the light absorption layer 9 is formed is only a range on which the patterning has been performed in the region A, while in the region B on which no patterning has been performed, the dielectric film 81 remains with a thickness as it was formed.

Next, as shown in (c1) and (c2) of FIG. 6, in Process 3, the second dielectric film 82 made of SiO₂ is formed with a thickness of 50 nm with use of the CVD method in the whole of the region A and the region B. This enables the second dielectric film 82 to be formed on the first dielectric film 81 and the light absorption layer 9 (second dielectric film formation step). A layered film of the first dielectric film 81 and the second dielectric film 82, both of which are formed in this way, is the dielectric film 8 according to the present embodiment.

At this time, a step A of 50 nm is produced as a difference in thickness between the first dielectric film 81 and the light absorption layer 9 because, in the region A, the thickness of the first dielectric film 81 is different from the thickness of the light absorption layer 9.

Next, as shown in (d1) and (d2) of FIG. 6, in Process 4, a resist 20 patterned into a predetermined shape is formed such that the dielectric film 8 is etched to create an opening for (i.e., to expose) the contact layer 7 in the following process. The resist 20 is patterned such that the dielectric film 8 has an opening on a top face of the ridge portion. In other words, the resist 20 is formed so as to expose the dielectric film 8 formed on a top face of the ridge portion and an upper side of the ridge portion. It is noted that a resist etch-back method with use of oxygen plasma processing can be used for formation of this opening.

Moreover, at this time, a resist surface A of the region A is lower than a resist surface B of the region B by only 50 nm for the step A. This is because resist is simultaneously applied to the region A and the region B under the same condition and because the step A makes the resist-applied surface in the region A lower than the resist-applied surface in the region B by only 50 nm for the step A.

Next, as shown in (e1) and (e2) of FIG. 6, in Process 5, the dielectric film 8 exposed in Process 4 is removed by etching (ridge portion exposure step). In other words, the dielectric film 8 exposed from a resist opening is etched. This enables only the dielectric film 8 in contact with an upper portion of a side of the ridge portion to be selectively removed, so that the dielectric film 8 in contact with a lower portion of sides of the ridge portion remains. More specifically, in the contact layer 7, the dielectric film 8 formed on a top face and a side surface is removed, and in the second cladding layer 6, the dielectric film 8 on an upper portion of a side of the ridge 6a is removed such that a part of the side of the ridge 6a is exposed at a desired height from the dielectric film 8.

It is noted that etching of the dielectric film 8 can be performed by wet etching with use of buffered hydrofluoric acid. Moreover, an etching time is determined by the time required to remove the dielectric film 8 in the region A or the region B at a given thickness. In the present embodiment, the etching time is set such that the thickness H_{B} is 100 nm, which is the thickness of exposure of the second cladding layer 6 and the contact layer 7 in the region B from the dielectric film 8. At this time, because etching is simultaneously performed in the region A and the region B, the thickness H_{A}, which is a thickness of exposure of the second cladding layer 6 and the contact layer 7 from the dielectric film 8 in the region A whose resist surface is lower by the step A, is 150 nm, which is longer than the above mentioned H_{B} in the region B by only 50 nm for the step A.

Later, although not illustrated, the first electrode 10 is formed such that the ridge portion is covered (electrode formation step). At this time, the first electrode is formed such that the first electrode is in contact with at least an exposed part of the ridge portion of the region A. In the present embodiment, the first electrode 10 is formed on a top face and a side of the contact layer 7, a part exposed from the dielectric film 8 in a side wall portion of the ridge 6a of the second cladding layer 6, and the whole surface of the dielectric film 8.

Finally, the second electrode 11 is formed on a reverse side of the substrate 1 after grinding and polishing the substrate 1 at a desired thickness. This enables the nitride semiconductor laser device 100 according to the present embodiment to be manufactured. As described above, in FIG. 6, the CVD method is used as a method of forming the dielectric film 8 (the first dielectric film 81 and 82), but this is not the only method. Other than the CVD method, for example, a thermal CVD method and a plasma CVD method can be used.

Moreover, a value of the step A of the dielectric film 8 can be adjusted by setting any values for thicknesses of the first dielectric film 81 and the light absorption layer 9. Therefore, a magnitude relationship between H_{A} in the region A and H_{B} in the region B can be optionally adjusted. For example, because the value of the step A is a thickness of the first dielectric film 81 minus a thickness of the light absorption layer 9, and H_{A} is H_{B} plus the step A, in the case where a thickness of the light absorption layer 9 is smaller than a thickness of the first dielectric film 81, the step A is a positive value, resulting in H_{A}>H_{B}. Meanwhile, in the case where the thickness of the light absorption layer 9 is equal to the thickness of the first dielectric film 81, a value of the step A is zero, resulting in H_{A}=Hg. Furthermore, in the case where the thickness of the light absorption layer 9 is greater than the thickness of the first dielectric film 81, a value of the step A is negative, resulting in H_{A}<H_{B}.

It is noted that the above method of forming the dielectric film 8 is an example and a different formation method can be used as long as a form similar to the form of the dielectric film 8 can be formed.

Moreover, it is preferable that the light absorption layer 9 be provided in a position between 1.2 μm and 3.3 μm inclusive from the centre of the ridge. This is because in the case where a distance of the light absorption layer 9 from the center of the ridge is less than 1.2 μm, an overlapping of the basic lateral mode light and the light absorption layer 9 increases and an internal loss increases, thus having adverse effects, such as an increase in the threshold current and a decrease in the luminescence efficiency, on the laser characteristics. Moreover, this is because in the case where a distance S from the center of the ridge of the light absorption layer 9 is over 3.3 μm, as a position of the step A, which is a difference between the dielectric film 8 and the light absorption layer 9, is away from the center of the ridge, an influence of the step A becomes small at the time of resist application in Process 4 shown in (d1) of FIG. 6 and opening positions of the dielectric film 8 are in the same height in the region A and the region B, and therefore the dielectric film 8 cannot be etched under a condition of H_{A}>H_{g}. It is noted that a difference between H_{A} in the region A and H_{B} in the region B is also larger because as the step A becomes closer to the center of the ridge, the step A becomes greater at the time of resist application in Process 4 as shown in (d1) of FIG. 6.

Therefore, a thickness of the ridge portion exposed from the dielectric film 8 is largest in a region where a distance S between the light absorption layer 9 and the center of the ridge in the second cladding layer 6 is smallest. In the nitride semiconductor laser device 100 according to the present embodiment, H_{A} is largest when the distance S from the center of the ridge to the light absorption layer 9 is 1.2 μm. This is because as the step A, which is a difference between the dielectric film 8 and the light absorption layer 9 in the region A, becomes closer to the centre of the ridge, the resist surface A becomes more susceptible to an effect of the step A at the time of resist application in Process 4 shown in (d1) of FIG. 6, and then becomes lower. In this way, by also adjusting the distance S of the light absorption layer 9 from the center of the ridge, it is possible to control a thickness of a side wall portion of the ridge portion exposed from the dielectric film 8.

It is noted that in the nitride semiconductor laser device 100 according to the present embodiment, the light absorption layer 9 is formed in the region A, but the light absorption layer 9 is not necessarily required to be formed. Even in the absence of the light absorption layer 9, by forming the dielectric film 8 to satisfy H_{A}>H_{B}, it is possible to obtain an effect similar to the effect of the nitride semiconductor laser device 100 according to the present embodiment. This is because even if the light absorption layer 9 is not formed in the region A but if a form of the dielectric film 8 is set at H_{A}>H_{B}, it is possible to similarly obtain an effect of promoting heat dissipation from the front end face 100a.

Moreover, in the absence of the light absorption layer 9, an absorption of light distribution in the light absorption layer 9 decreases, thus further decreasing the internal loss. Therefore, compared with the case where the light absorption layer 9 is included, an amount of heat generated by the Joule loss and the internal loss can be decreased, and the structure of the dielectric film 8 satisfying H_{A}>H_{B} makes it possible to further improve the reliability characteristics including an improvement in the COD level by heat dissipation from the front end face 100a, and the optical characteristics including a decrease in the amount of change in the horizontal FFP relative to the light output. It is noted that in the absence of the light absorption layer 9, there are influences such as an influence of a turbulence of the horizontal FFP waveform caused by light reflected from the front end face 100a. Therefore, it is preferable that there be no interference of reflected light with the basic transverse mode light by the creation of a configuration to decrease a reflectance by coating the front end face 100a with a low reflection film and the like.

As described above, with the nitride semiconductor laser device 100 according to the first embodiment of the present invention, by determining H_{A}>H_{B} as a relationship between H_{A}, which is a thickness of exposure of the second cladding layer 6 and the contact layer 7 from the dielectric film 8 in the region A on the front end face 100a side, and H_{B}, which is a thickness of exposure of the second cladding layer 6 and the contact layer 7 in the region B from the dielectric film 8, it is possible to improve heat dissipation properties on the front end face 100a side of the nitride semiconductor laser device 100, and to improve the COD level, and stabilize the horizontal FFP more than the nitride semiconductor laser device that satisfies H_{A}=H_{B}. Therefore, it is possible to realize the nitride semiconductor laser device, especially a high output nitride semiconductor device used for BD, with simultaneously improved the reliability characteristics and the FFP characteristics.

### Second Embodiment

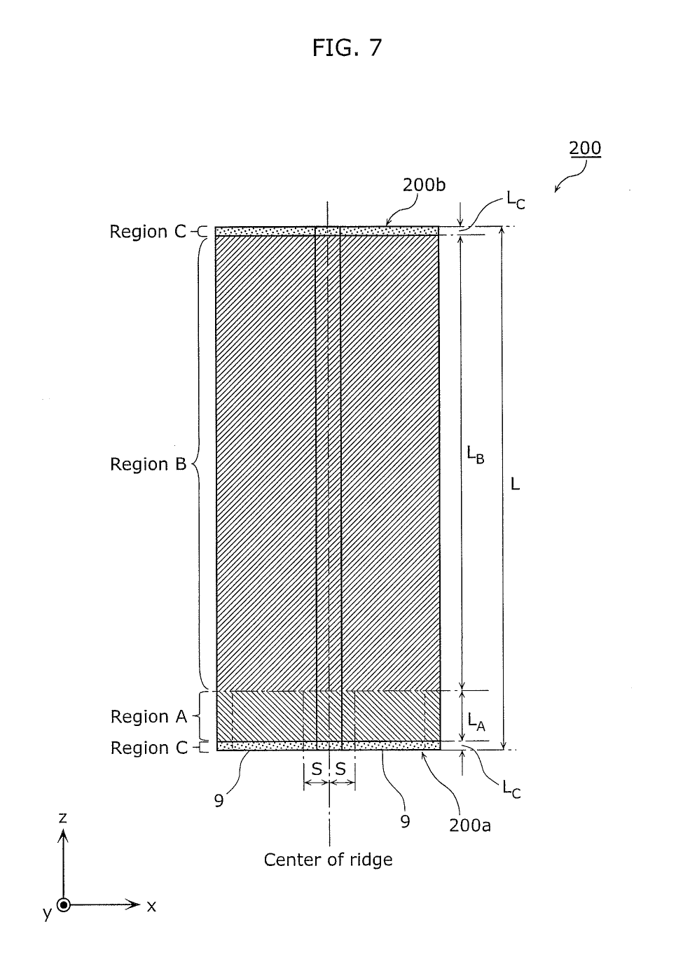

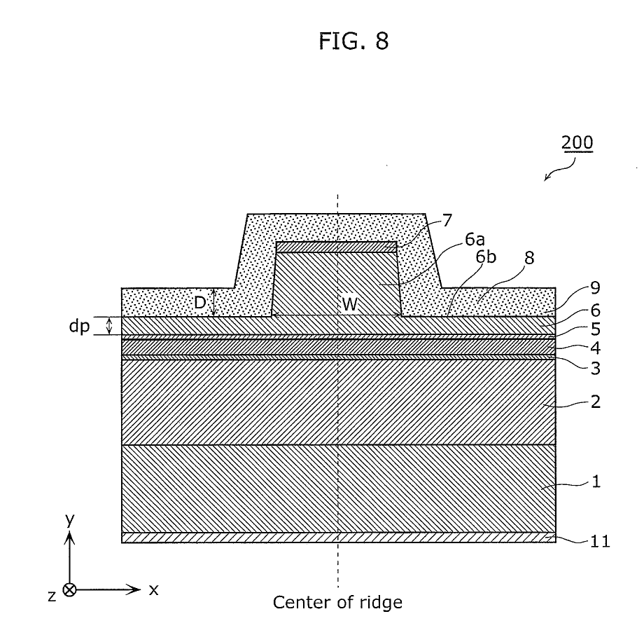

Next, a structure of a nitride semiconductor laser device according to the second embodiment of the present invention shall be described with use of FIG. 7 and FIG. 8. FIG. 7 is a cross-sectional view of the nitride semiconductor laser device according to the second embodiment of the present invention. Moreover, FIG. 8 is a cross-sectional view of the nitride semiconductor laser device in a region C according to the second embodiment of the present invention. It is noted that in the present embodiment, differences from the first embodiment of the present invention will be mainly described, and in FIG. 7 and FIG. 8, the same numerals are attached to components shown in FIGS. 1 to 3.

A difference of the nitride semiconductor laser device 200 according to the second embodiment of the present invention shown in FIG. 7 from the nitride semiconductor laser device 100 according to the first embodiment of the present invention shown in FIG. 1 is that the nitride semiconductor laser device 200 according to the second embodiment of the present invention includes a non-current injection region (region C) on a front end face 200a and a rear end face 200b.

In the present embodiment, the non-current injection region (region C) has a length L_{C} of 5 μm in a z axis direction. Moreover, a length L_{A} in the z axis direction of the region A is set at 40 μm and a length L_{B} in the z axis direction of the region B is set at 750 μm. It is noted that an overall length L (L_{A}+L_{B}+L_{C}) of a laser resonator is 800 μm similarly to the length in the first embodiment.

As shown in FIG. 8, in the non-current injection region (region C) of the nitride semiconductor laser device 200 according to the second embodiment of the present invention, the dielectric film 8 is not etched but is formed such that the contact layer 7 is not exposed, and the first electrode 10 is also not formed.

In conclusion, the nitride semiconductor laser device 200 according to the second embodiment of the present invention includes a non-current injection region on the front end face 200a and the rear end face 200b, and therefore no current is injected into in the vicinity of the front end face 200a and the rear end face 200b. This enables the front end face 200a and the rear end face 200b to avoid causing a Joule loss from a series resistance in the second cladding layer 6 and the contact layer 7. Therefore, an establishment of a relationship H_{A}>H_{B} where H_{A} is in the region A and H_{B} is in the region B enables an amount of heat generation in the vicinity of the front end face 200a and the rear end face 200b to further decrease, thus enabling the COD level to be further improved.

It is noted that it is preferable that the non-current injection region, as shown in the present embodiment, include both the front end face 200a and the rear end face 200b, but the non-current injection region in the rear end face 200b can be omitted. This is because in a general high output nitride semiconductor laser, so that an end face reflectance of a side of the front end face is set to be lower than an end face reflectance of a side of the rear end face, a light intensity in the front end face region is higher than a light intensity in the rear end face region, and an amount of heat generation in the front end face is larger than an amount of heat generation in the rear end face. Therefore, an influence on the COD level is limited even though a non-current injection region in the rear end face is omitted.

Moreover, in the present embodiment, it is preferable that the non-current injection region (region C) have a length L_{C} of 10 μm or less in a z axis direction. In the case where the non-current injection region is over 10 μm, light absorption by the active layer 4 in the non-current injection region increases, which may cause adverse effects on the laser characteristics, including a deterioration in linearity of a light output with respect to an injected current.

As described above, with the nitride semiconductor laser device 200 according to the second embodiment of the present invention, by including the non-current injection region at least on the front end face 200a side, heat dissipation properties on the front end face side can be further improved compared with the nitride semiconductor laser device 100 according to the first embodiment of the present invention. This enables the COD level to be further improved and the horizontal FFP to be further stabilized. Therefore, it is possible to realize the nitride semiconductor laser device, especially a high output semiconductor laser device used for BD, with simultaneously improved reliability characteristics and FFP characteristics.

As described above, the nitride semiconductor laser device according to the present invention shall be described based on the embodiments, but the present invention is not limited to the embodiments. Without departing from the spirit and scope of the present invention, a variation of the embodiment conceived by those skilled in the art falls within the scope of this invention. Moreover, without departing from the spirit and scope of the present invention, any combination of components in the embodiments is acceptable.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is effective as a semiconductor laser device used in an optical pickup device in an optical disc system, and especially effective as a nitride semiconductor laser device suitable for a BD optical disc device.

What is claimed is:

1. A nitride semiconductor laser device comprising:
a front end face that is a light-emitting end face;
a rear end face opposite to said front end face;
a first semiconductor layer of a first conductivity type, which is formed above a substrate;
an active layer formed above said first semiconductor layer;
a second semiconductor layer of a second conductivity type, which is formed above said active layer and includes a ridge portion and a planar portion;
an electrode formed above said ridge portion; and
a dielectric film formed on a part of a side wall portion of said ridge portion and extending to said planar portion,
wherein a part of said side wall portion of said ridge portion is exposed from said dielectric film along a direction from said front end face to said rear end face,
where a region from said front end face to a predetermined position between said front end face and said rear end face is determined as a region A, and a region from the predetermined position to said rear end face is determined as region B,
a thickness of the exposed part of said ridge portion in the region A is greater than a thickness of the exposed part of said ridge portion in the region B, the exposed part being exposed from said dielectric film, and
in at least the region A, said electrode is in contact with the part of said ridge portion exposed from said dielectric film.

2. A nitride semiconductor laser device comprising:
a front end face that is a light-emitting end face;
a rear end face opposite to said front end face;
a first semiconductor layer of a first conductivity type, which is formed above a substrate;
an active layer formed above said first semiconductor layer;
a second semiconductor layer of a second conductivity type, which is formed above said active layer and includes a ridge portion and a planar portion;
an electrode formed above said ridge portion; and
a dielectric film formed on a part of a side wall portion of said ridge portion and extending to said planar portion,
wherein a part of said side wall portion of said ridge portion is exposed from said dielectric film along a direction from said front end face to said rear end face,
where a region from said front end face to a predetermined first position between said front end face and said rear end face is determined as a non-current injection region, a region from the first position to a predetermined second position between the first position and said rear end face is determined as a region A, and a region from the second position to a predetermined third position between the second position and said rear end face is determined as region B,
a thickness of the exposed part of said ridge portion in the region A is greater than a thickness of the exposed part of said ridge portion in the region B, the exposed part being exposed from said dielectric film, and
in at least the region A, said electrode is in contact with the part of said ridge portion exposed from said dielectric film.

3. The nitride semiconductor laser device according to claim 2,
wherein the third position is a position of said rear end face.

4. The nitride semiconductor laser device according to claim 2,
wherein the non-current injection region also includes a region from the third position to said rear end face.

5. The nitride semiconductor laser device according to claim 2,
wherein a length from said front face end to the first position is 10 μm or less.

6. The nitride semiconductor laser device according to claim 1,
wherein a difference in thickness between the exposed part of said ridge portion in the region A and the exposed part of said ridge portion in the region B is 20 nm or more, the exposed parts being exposed from said dielectric film.

7. The nitride semiconductor laser device according to claim 1,
wherein a length of the region A in the direction from said front end face to said rear end face is between 10 μm and 200 μm inclusive.

8. The nitride semiconductor laser device according to claim 1,
wherein said dielectric film mainly includes silicon dioxide, zirconium dioxide, silicon nitride, or tantalum oxide.

9. The nitride semiconductor laser device according to claim 1,
wherein said electrode is made of at least one metal selected from a group consisting of palladium, titanium, platinum, gold, nickel, chromium, and molybdenum, or is made of an alloy of the metals.

10. The nitride semiconductor laser device according to claim 1,
wherein an absorption layer for absorbing light with an oscillation wavelength of said nitride semiconductor laser is formed above said planar portion in the region A.

11. The nitride semiconductor laser device according to claim 10,
wherein said absorption layer is provided at a distance of 1.2 μm to 3.3 μm inclusive from a center of said ridge portion, the distance being in a width direction of said ridge portion, and
a thickness of the exposed part of said ridge portion in the region A is largest in a position where the distance between said absorption layer and the center of said ridge portion is smallest, the exposed part being exposed from said dielectric film.

12. The nitride semiconductor laser device according to claim 1,
wherein said second semiconductor layer includes a cladding layer and a contact layer formed above said cladding layer,
said cladding layer includes a ridge and said planar portion on a surface,
a width of said contact layer is the same as a width of a top face of said ridge, and
said ridge portion of said second semiconductor layer is composed of said ridge of said cladding layer and said contact layer.

13. A method of manufacturing a nitride semiconductor laser device including a front end face that is a light-emitting end face, and a rear end face opposite to the front end face, said manufacturing method comprising:
sequentially forming, above a substrate, a first cladding layer of a first conductivity type, an active layer, a second cladding layer of a second conductivity type, and a contact layer of the second conductivity type;
forming a ridge portion and a planar portion by selectively etching the second cladding layer and the contact layer;
forming, above the planar portion, a first dielectric film to cover the ridge portion;
selectively etching the first dielectric film on the planar portion, and forming, in the etched portion, an absorption layer having a thickness smaller than a thickness of the first dielectric film;
forming a second dielectric film on the first dielectric film and on the absorption layer;
selectively exposing a top face and a part of a side of the ridge portion from the first dielectric film and the second dielectric film by etching the first dielectric film and the second dielectric film; and
forming an electrode to cover at least the exposed ridge portion,
where a region from the front end face to a predetermined position between the front end face and the rear end face is determined as a region A, and a region from the predetermined position to the rear end face is determined as a region B,
in said forming of an absorption layer, the absorption layer is formed in the region A,
in said selectively etching, a thickness of the exposed part of the ridge portion in the region A is greater than a thickness of the exposed part of the ridge portion in the region B, the exposed part being exposed from the dielectric film, and
in said forming of an electrode, in at least the region A, the electrode is in contact with the part of the ridge portion exposed from the dielectric film.
